(19) United States
(12) Patent Application Publication
(10) Pub. No.: US 2017/0076791 A1
(43) Pub. Date: Mar. 16, 2017

(54) SEMICONDUCTOR MEMORY DEVICE

(71) Applicant: KABUSHIKI KAISHA TOSHIBA, Tokyo (JP)

(72) Inventors: Masahiro TAKAHASHI, Yokohama Kanagawa (JP); Katsuyuki FUJITA, Nishitokyo Tokyo (JP)

(73) Assignee: KABUSHIKI KAISHA TOSHIBA, Tokyo (JP)

(21) Appl. No.: 15/065,846

(22) Filed: Mar. 9, 2016

Related U.S. Application Data
(60) Provisional application No. 62/216,753, filed on Sep. 10, 2015.

(51) Int. Cl. G11C 13/00; G11C 11/16

(52) U.S. Cl. CPC G11C 13/0004; G11C 11/1675

(57) ABSTRACT

According to one embodiment, a semiconductor memory device includes: first and second memory cells each including a variable resistance element; a first sense amplifier having a first input terminal coupled to the first memory cell; a second sense amplifier having a first input terminal coupled to the second memory cell; and a first current generator including a first resistance element coupled to a second input terminal of the first sense amplifier and a second input terminal of the second sense amplifier, and generating a first current supplied to the first sense amplifier or the second sense amplifier. The first sense amplifier is set to an active state and the second sense amplifier is set to an inactive state in a read operation of the first memory cell.

### CROSS-REFERENCE TO RELATED APPLICATIONS

This application claims the benefit of U.S. Provisional Application No. 62/216,753, filed Sep. 10, 2015, the entire contents of which are incorporated herein by reference.

### FIELD

Embodiments described herein relate generally to a semiconductor memory device.

### BACKGROUND

As a type of semiconductor storage device, a resistance change memory is known. As a type of resistance change type memory, a magnetoresistive random access memory (MRAM) is known. An MRAM is a memory device adopting a magnetic element having a magnetoresistive effect as a memory cell for storing information, and has attracted attention as a next-generation memory device having fast operation, large storage capacity, and non-volatility. Research and development has been in progress to replace a volatile memory, such as a DRAM and SRAM, with an MRAM.

### BRIEF DESCRIPTION OF THE DRAWINGS

FIG. 1 is a block diagram of a semiconductor memory device according to the first embodiment;

FIGS. 2 and 3 are block diagrams of a bank and a region AA in the semiconductor memory device according to the first embodiment;

FIG. 4 is a circuit diagram of a cell array and a sense amplifier in the semiconductor memory device according to the first embodiment;

FIG. 5A is a cross-sectional view of an exemplary configuration of a variable resistor element in the semiconductor memory device according to the first embodiment;

FIG. 5B is a drawing to explain a write operation at the variable resistor element in the semiconductor memory device according to the first embodiment, and is a cross-sectional view of the variable resistor element in a parallel state;

FIG. 5C is a drawing to explain a write operation at the variable resistor element in the semiconductor memory device according to the first embodiment, and is a cross-sectional view of the variable resistor element in an anti-parallel state;

FIG. 6 is a circuit diagram of reference current generators in the semiconductor memory device according to the first embodiment;

FIG. 7 is a plane view of the sense amplifiers and the reference current generators in the semiconductor memory device according to the first embodiment;

FIG. 8 is a timing chart indicating a read operation at the semiconductor memory device according to the first embodiment;

FIGS. 9A and 9B show an exemplary connection between the sense amplifiers and the reference resistor element;

FIG. 10 is a circuit diagram of the reference current generators at the semiconductor memory device according to the first example of the second embodiment;

FIG. 11 is a plane view of the sense amplifiers and the reference current generators in the semiconductor memory device according to the first example of the second embodiment;

FIG. 12 is a circuit diagram of the reference current generators in the semiconductor memory device according to the second example of the second embodiment;

FIG. 13 is a plane view of the sense amplifiers and the reference current generators in the semiconductor memory device according to the second example of the second embodiment;

FIG. 14 is a circuit diagram of the reference current generator in the semiconductor storage apparatus according to the third example of the second embodiment; and

FIG. 15 is a plane view of the sense amplifiers and the reference current generator in the semiconductor memory device according to the third example of the second embodiment.

### DETAILED DESCRIPTION

In general, according to one embodiment, a semiconductor memory device includes: first and second memory cells each including a variable resistance element; a first sense amplifier having a first input terminal coupled to the first memory cell; a second sense amplifier having a first input terminal coupled to the second memory cell; and a first current generator including a first resistance element coupled to a second input terminal of the first sense amplifier and a second input terminal of the second sense simplifier, and generating a first current which is based on the first resistance element and in supplied to the first sense amplifier or the second sense amplifier. The first sense amplifier is set to an active state and the second sense amplifier is set to an inactive state in a read operation at the first memory cell.

### 1 First Embodiment

A semiconductor memory device according to the first embodiment will be explained.

1.1 Overall Configuration of Semiconductor Memory Device

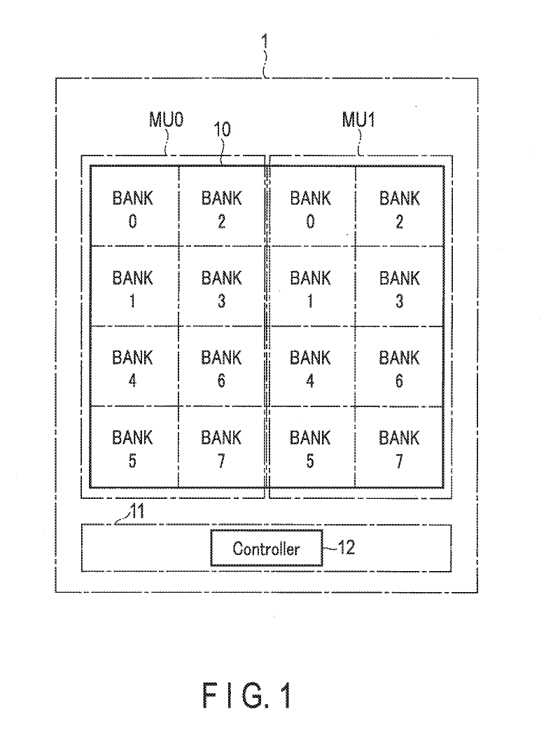

The overall configuration of the semiconductor memory device according to the present embodiment is first explained. FIG. 1 is a block diagram of the semiconductor memory device according to the first embodiment. Herein, an MRAM for storing data using a magnetoresistive effect element (an MTJ element) as a variable resistance element is explained as an example. Note that in the following explanation the terms “connect” and “couple” should be construed to include not only a direct connection, but also a physical or electrical connection through an intervening element, unless otherwise mentioned. Also note that one edge of a transistor indicates one of either a source or a drain, and the other edge indicates one of the other drain or source.

As shown in FIG. 1, an MRAM 1 includes a core unit 10 and a peripheral circuit unit 11. The core unit 10 includes two memory units MU0 and MU1. The memory unit MU writes data to and reads data from a memory cell. The memory units MU0 and MU1 are operable independently or concurrently. Note that the number of the memory units MU is not limited to two; it may be one, three, or more. Each memory unit MU includes eight banks BANK0 to BANK7. One bank BANK is a unit accessible by a host device (not shown). Accordingly, in a memory unit MU0, for example, the host device can select one of the banks BANK0 to BANK7. Note that the number of banks BANK included in one memory unit MU is not limited to eight, and it can be set arbitrarily.

The peripheral circuit unit 11 includes a controller 12. The controller 12 controls all operations of the MRAM 1.

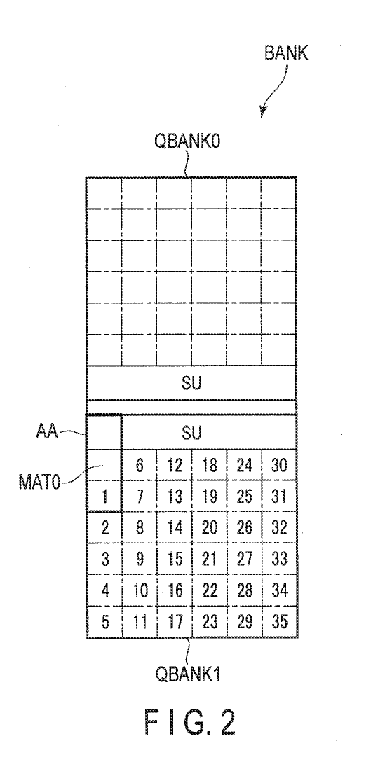

Next, the configuration of the bank BANK is explained with reference to FIG. 2. FIG. 2 is a block diagram of the bank BANK in the semiconductor memory device according to the first embodiment.

As shown in FIG. 2, a bank BANK in each memory unit MU includes two quarter banks QBANK0 and QBANK1, and sense units SU respectively corresponding to the quarter banks QBANK. Thus, if the memory units MU0 and MU1 are put together, each of the banks BANK0 to BANK7 has four quarter banks QBANK.

The quarter bank QBANK is a unit of a read and write operation performed individually in a bank BANK. The controller 12 can perform the data read and write operation for each quarter bank QBANK. Note that the number of the quarter banks QBANK included in one bank BANK is not limited to two, and it can be arbitrarily set. Each quarter bank QBANK includes a plurality of mats MAT. The mat MAT is a unit obtained by dividing a cell array in a quarter bank QBANK into a plurality of units. In the example shown in FIG. 2, one quarter bank QBANK includes 6 (rows)×6 (columns)=36 mats MAT. Note that the number of the mats MAT included in one quarter bank can be arbitrarily determined.

At the time of reading data, for example, the sense unit SU reads data from selected memory cells.

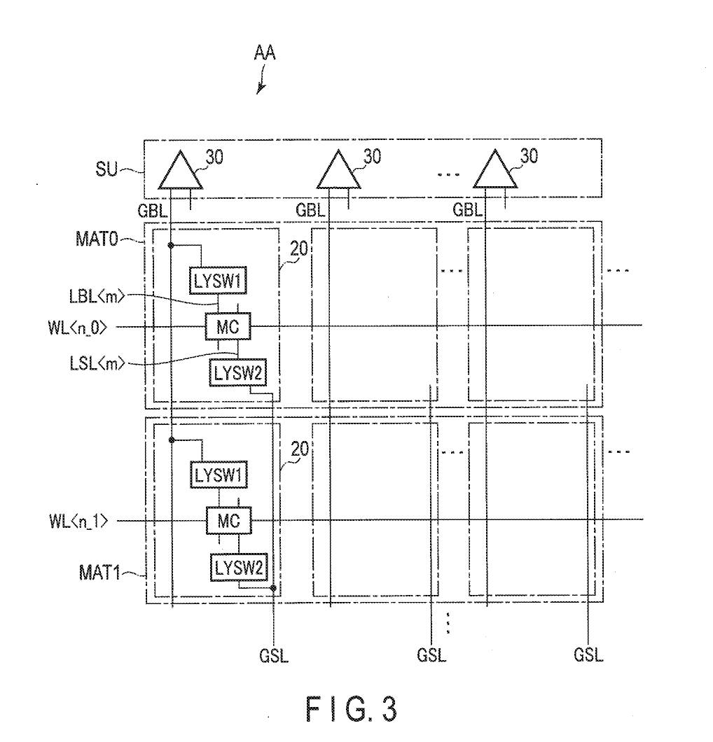

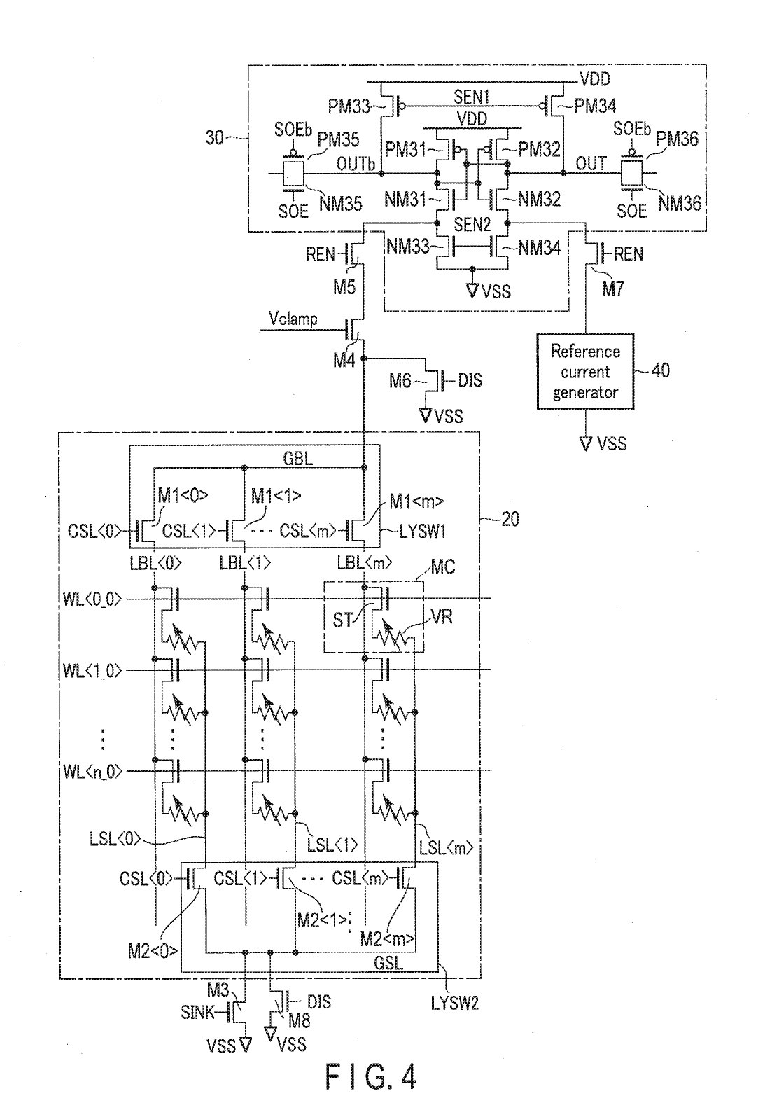

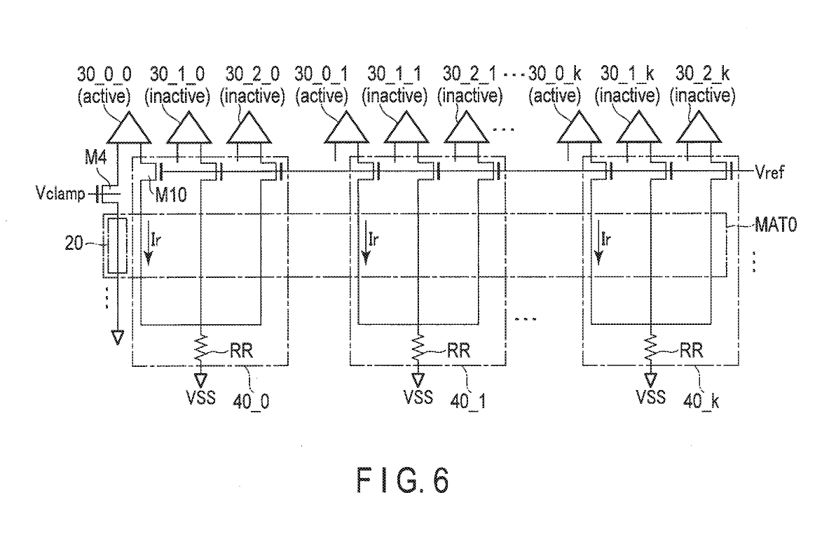

Next, the relationship between the mats MAT0 and MAT1 indicated by the region AA and the sense unit SU is explained with reference to FIG. 3. FIG. 3 is a block diagram of the region AA in the semiconductor memory device according to the first embodiment. In the example shown in FIG. 3, for brevity, a connection between one of the two input terminals of the sense amplifier 30 and the cell array 20 is shown, and a connection of the other terminal is omitted. One memory cell MC is shown in the cell array 20, as an example. The details of the sense amplifier 30 and the cell array 20 will be explained later with reference to FIG. 4 and FIG. 6.

As shown in FIG. 3, each mat MAT includes a plurality of cell arrays 20 arranged in the same row. Each cell array 20 includes local column switches LYSW1, LYSW2, and a plurality of memory cells MC.

The local column switch LYSW1 is coupled to m+1 (m is an integer of 0 or more) local bit lines LBL<0> to LBL<m> (not shown). The local column switch LYSW2 is coupled to the same number of local source lines LSL<0> to LSL<m>. In the explanation below, when each of a plurality of local bit lines or each of a plurality of local source lines is not individually identified, it will be simply denoted as a local bit line LBL or a local source line LSL. In the cell array 20, the local column switch LYSW1 selects one local bit line LBL and couples it to a global bit line GBL. Similarly, the local column switch LYSW2 selects one local source line LSL and couples it to a global source line GSL.

Of the cell arrays 20 arranged in a matrix in the quarter bank QBANK, the local column switches LYSW1 of the cell arrays 20 arranged in the same column are commonly coupled to one global bit line GBL, and the local column switches LYSW2 are commonly coupled to one global source line GSL. Of the cell arrays 20 arranged in the same row, the memory cells MC arranged on the same row are commonly coupled to any of n+1 (n is an integer of 0 or more) word lines WL (not shown). In the following, n+1 word lines corresponding to the mat MAT0 will be denoted as WL<0_0> to WL<n_0>, and n+1 word lines corresponding to the mat MAT1 will be denoted as WL<0_1> to WL<n_1>. In the explanation below, when each of a plurality of word lines is not individually identified, it will be denoted as a word line WL. The memory cell MC is arranged at locations where a word line WL intersects both a local bit line LBL and a local source line LSL in the cell array 20.

The sense unit SU includes a plurality of sense amplifiers 30 per mat MAT. When data is read, the sense amplifier 30 senses data read out to the global bit line GBL. The sense amplifier 30 includes two input terminals. One of the input terminals is coupled to the cell arrays 20 arranged in the same column via the global bit line GBL. Thus, the sense unit SU includes the same number of sense amplifiers 30 as the number of global bit lines GBL.

1. 1. 1 Configuration of Cell Array

Next, the configuration of the cell array 20 will be explained with reference to FIG. 4. FIG. 4 is a circuit diagram of the cell array 20 and the sense amplifier 30 in the semiconductor memory device according to the first embodiment. Note that in the example shown in FIG. 4 the cell array 20 included in the mat MAT0 is explained, but the other cell arrays 20 in the mat MAT0 and the other cell arrays 20 in the other mats MAT have the same configuration.

As shown in FIG. 4, the cell array 20 is coupled to one of the input terminals (hereinafter, “the first input terminal”) of the sense amplifier 30. The other input terminal (hereinafter, “the second input terminal”) of the sense amplifier 30 is coupled to the reference current generator 40 included in the MRAM 1. When data is read, for example, the reference current generator 40 generates a reference current Ir which is an intermediate current between a cell current corresponding to “1” data and a cell current corresponding to “0” data. The details of the sense amplifier 30 and the reference current generator 40 will be described later.

The cell array 20 has memory cells MC which are at locations where the word lines WL<0_0> to WL<n_0> intersect both the local bit lines LBL<0> to LBL<m> and the local source lines LSL<0> to LSL<m>. In the example shown in FIG. 4, the cell array 20 includes (n+1)×(m+1) memory cells MC. Note that the number of the memory cells MC is arbitrary.

The memory cell MC includes, for example, a variable resistance element VR and a select transistor ST. The variable resistance element VR varies its resistance value as a result of a change in a magnetization array or a crystal condition caused by applying a necessary current (or voltage) to the variable resistance element VR. The variable resistance element VR includes, for example, an MTJ element, a phase change element, and a ferroelectric element. In the present embodiment, a case where a variable resistance element VR is an MTJ element is explained. The select transistor ST is in an on state when the memory cell MC is selected.

One end of the variable resistance element VR is coupled to one end of the select transistor ST. In the cell array 20, the other ends of the variable resistance elements VR of the memory cells MC arranged in the same column are commonly coupled to any of the local source lines LSL, and the other ends of the select transistors ST are commonly coupled to any of the local bit lines LBL. In the cell array 20, the gates of the select transistors ST arranged in the same row are commonly coupled to any of the word lines WL.

One end of the local source lines LSL<0> to LSL<m> is respectively coupled to one end of the column selection transistors M2<0> to M2<m>. The other ends of the column selection transistors M2<0> to M2<m> are commonly coupled to the global source line GSL. Column selection signals CSL<0> to CSL<m> are respectively input to the gates of the column selection transistors M2<0> to M2<m>. Thus, the column selection transistors M2<0> to M2<m> function as the local column switch LYSW2, and they select any one of the local source lines LSL<0> to LSL<m> in accordance with the column selection signals CSL<0> to CSL<m>.

The global source line GSL is coupled to one end of an NMOS transistor (sink transistor) M3. The other end of the sink transistor M3 is grounded (a ground potential VSS is applied to the other end of the sink transistor M3), and a sink signal SINK is input to the gate. The global source line GSL is coupled to one end of the NMOS transistor (discharge transistor) M8. The other end of the discharge transistor M8 is grounded, and a discharge signal DIS is input to the gate.

One end of the local bit lines LBL<0> to LBL<m> is respectively coupled to one end of the column selection transistors M1<0> to M1<m>. The other ends of the column selection transistors M1<0> to M1<m> are commonly coupled to the global bit line GBL. Column selection signals CSL<0> to CSL<m> are respectively input to the gates of the column selection transistors M1<0> to M1<m>. Thus, the column selection transistors M1<0> to M1<m> function as the local column switch LYSW1, and they select any one of the local bit lines LBL<0> to LBL<m> in accordance with the column selection signals CSL<0> to CSL<m>.

The global bit line GBL is coupled to one end of an NMOS transistor (clamp transistor) M4. The other end of the clamp transistor M4 is coupled to one end of an NMOS transistor (read enable transistor) M5, and a clamp signal Vclamp is input to the gate. The clamp transistor M4 is used to clamp a voltage applied to the global bit line GBL to a voltage in accordance with the clamp voltage Vclamp. The other end of the read enable transistor M5 is electrically coupled to the first input terminal of the sense amplifier 30, and a read enable signal REN is input to the gate. The global bit line GBL is coupled to one end of the NMOS transistor (discharge transistor) M6. A ground potential VSS is applied to the other end of the discharge transistor M6, and a discharge signal DIS is input to the gate.

1. 1. 2 Configuration of Variable Resistance Element

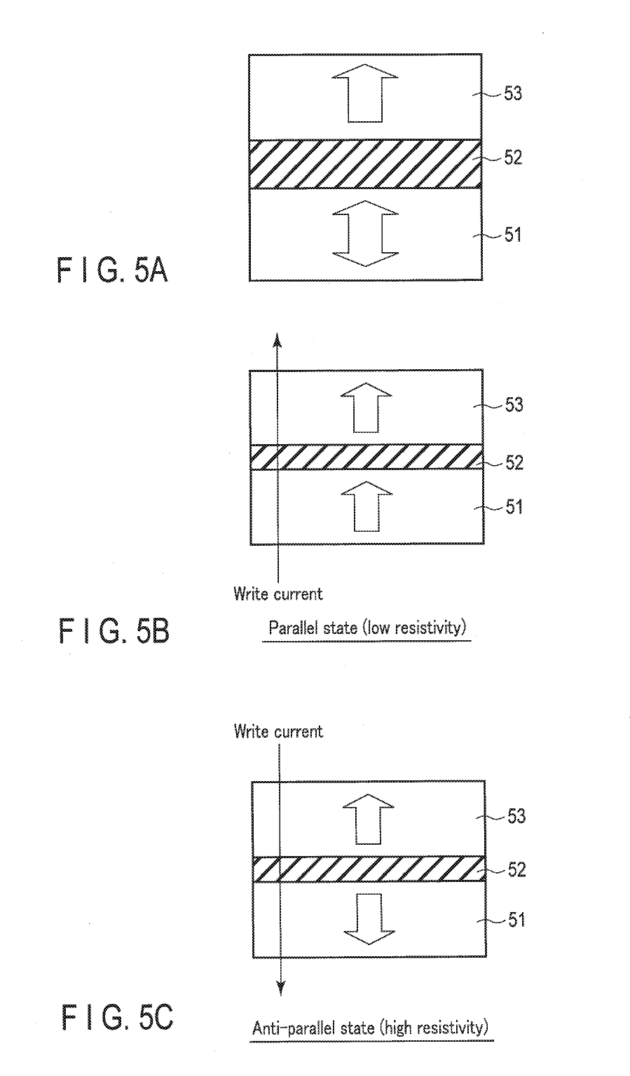

Next, the variable resistance element VR will be explained with reference to FIGS. 5A, 5B, and 5C.

FIG. 5A is a cross-sectional view of an exemplary configuration of the variable resistance element (magnetoresistive effect element) VR. Herein, as a variable resistance element VR, a storage layer 51, a tunnel barrier layer 52, and a reference layer 53 are mainly presented.

As shown in FIG. 5A, the variable resistance element VR includes a multi-layered structure consisting of the storage layer 51 which is a ferromagnetic layer, the reference layer 53 which is a ferromagnetic layer, and the tunnel barrier layer 52 which is a non-magnetic layer formed therebetween.

The storage layer 51 is a ferromagnetic layer in which a magnetization direction is variable, and has perpendicular magnetic anisotropy. Herein, perpendicular magnetic anisotropy means that a magnetization direction is perpendicular or almost perpendicular with respect to a film surface (top surface/bottom surface). A variable magnetization direction means that a magnetization direction varies with respect to a preset write current. Being almost perpendicular means that a residual magnetization direction falls within the range of 45<θ≦90 with respect to a film surface.

The tunnel barrier layer 52 is provided on the storage layer 51. The tunnel barrier layer 52 is a non-magnetic layer, and is made of MgO, for example.

The reference layer 53 is provided on the tunnel barrier layer 52. The reference layer 53 is a ferromagnetic layer in which a magnetization direction is not variable, and has perpendicular magnetic anisotropy. Herein, a non-variable magnetization direction means that a magnetization direction does not vary with respect to a preset write current. In other words, the reference layer 53 has a greater inverted energy barrier of the magnetization direction than the storage layer 51 has. Note that the magnetization direction of the storage layer 51 and the magnetization direction of the reference layer 53 are not limited to being perpendicular; it may be in an in-plane direction.

FIG. 5B is a drawing to explain a write operation of the variable resistance element VR in the semiconductor memory device according to the first embodiment, and is a cross-sectional view of the variable resistance element VR in a parallel state (P state). FIG. 5C is a drawing to explain a write operation of the variable resistance element VR in the semiconductor memory device according to the first embodiment, and is a cross-sectional view of the variable resistance element VR in an anti-parallel state (AP state).

The variable resistance element VR is, for example, a spin injection type magnetoresistive effect element. Accordingly, when data is written to the variable resistance element VR, or data is read from the variable resistance element VR, a current flows in a direction in two ways perpendicular to the film surface in the variable resistance element VR.

More specifically, data writing to the variable resistance element VR is carried out as described below.

As shown in FIG. 5B, when a current flows from the storage layer 51 to the reference layer 53, in other words, when electrons flowing from the reference layer 53 to the storage layer 51 are supplied, the electrons which are spin-polarized in a same direction as the magnetization direction of the reference layer 53 are injected to the storage layer 51. In this case, the magnetization direction of the storage layer 51 is adapted to a same direction as the magnetization direction of the reference layer 53. Thus, the magnetization direction of the reference layer 53 and the magnetization layer of the storage layer 51 will be in a parallel arrangement. When in this parallel arrangement, a resistance value of the variable resistance element VR becomes minimum. This case is defined as “0” data, for example.

On the other hand, as shown in FIG. 5C, when a current flows from the reference layer 53 to the storage layer 51, in other words, when electrons flowing from the storage layer 51 to the reference layer 53 are supplied, the electrons are reflected by the reference layer 53. Thus, the electrons which are spin-polarized in a direction opposite to the magnetization direction of the reference layer 53 are injected to the storage layer 51. In this case, the magnetization direction of the storage layer 51 is adapted to a direction opposite to the magnetization direction of the reference layer 53. Thus, the magnetization direction of the reference layer 53 and the magnetization direction of the storage layer 51 will be in an anti-parallel arrangement. Under this anti-parallel state, the resistance value of the variable resistance element VR becomes maximum. This case is defined as “1” data, for example.

Reading data from the variable resistance element VR is carried out as described below.

A read current is supplied to the variable resistance element VR. This read current is set at a value at which the magnetization direction of the storage layer 51 does not invert (i.e., a value smaller than a write current). By detecting a resistance value of the variable resistance element VR when the read current is supplied, the “0” data and “1” data can be read.

1. 1. 3 Configuration of Sense Amplifier

Returning to FIG. 4, the configuration of the sense amplifiers 30 will be explained. Note that the example shown in FIG. 4 illustrates an exemplary configuration of a current-sensing type sense amplifier, but it may be a voltage-sensing type sense amplifier.

As shown in FIG. 4, the second input terminal of the sense amplifier 30 is coupled to one end of the NMOS transistor (read enable transistor) M7. The other end of the read enable transistor M7 is coupled to the reference current generator 40, and a read enable signal REN is input to the gate.

The sense amplifier includes NMOS transistors NM31 to NM36, and PMOS transistor PM31 to PM36.

A source voltage VDD is applied to one end of the transistor PM31, and the other end is coupled to one end of the transistor NM31, and the gate is coupled to node OUT. The other end of the transistor NM31 is coupled to one end of the transistor NM33 and the first input terminal, and the gate is coupled to the node OUT. The transistors PM31 and NM31 function as a first inverter.

A source voltage VDD is applied to one end of the transistor PM32, and the other end is coupled to one end of the transistor NM32, and the gate is coupled to node OUTb. The other end of the transistor NM32 is coupled to one end of the transistor NM32 and the second input terminal, and the gate is coupled to the node OUTb. The transistors PM32 and NM32 function as a second inverter.

An input of the first inverter and an output of the second inverter are coupled to the node OUT, and an output of the first inverter and an input of the second inverter are coupled to the node OUTb. Thus, inverted data of the data retained by the node OUT is retained by the node OUTb.

The other end of the transistor NM33 is grounded, and a signal SEN2 is input to the gate.

The other end of the transistor NM34 is grounded, and a signal SEN2 is input to the gate.

A storage voltage VDD is applied to one end of the transistor PM33, and the other end is coupled to the node OUTb, and a signal SEN1 is input to the gate.

A source voltage VDD is applied to one end of the transistor PM34, and the other end is coupled to the node OUT, and a signal SEN1 is input to the gate.

One end of the transistor PM35 is coupled to the node OUTb, and a signal SOEb is input to the gate. One end of the transistor NM35 is coupled to the node OUTb, and a signal SOE is input to the gate. The transistors PM35 and NM35 function as a first pass transistor.

One end of the transistor PM36 is coupled to the node OUT, and a signal SOEb is input to the gate. One end of the transistor NM36 is coupled to the node OUT, and a signal SOE is input to the gate. The transistors PM36 and NM36 function as a second pass transistor.

1. 1. 4 Configuration of Reference Current Generator

Next, the configuration of the reference current generator 40 will be explained with reference to FIG. 6. FIG. 6 is a circuit diagram of the reference current generator 40 in the semiconductor memory device according to the first embodiment. In the present embodiment, a case where the reference current generator 40 includes a fixed resistance element thereby generating a reference current Ir is explained.

The example shown in FIG. 6 shows a plurality of sense amplifiers corresponding to the mats MAT arranged in the same column including the mat MAT0, and a plurality of reference current generators 40 coupled thereto.

In the present example, the sense amplifier 30 is expressed as sense amplifier 30_j_k. The variable j represents a number assigned to each of the sense amplifiers 30 included in one reference current generator 40 (in the present embodiment, j=0, 1 or 2), and the variable k represents a number assigned to a reference current generator 40 corresponding to one mat MAT (k is an integer of 0 or more).

Note that the read enable transistors M5 and M7 are omitted in the present example for brevity. As for the clamp transistor M4 and the cell arrays 20 coupled to the first input terminals of the sense amplifiers, only the sense amplifier 30_0_0 is shown, and the other components are omitted.

As shown in FIG. 6, three sense amplifiers 30 are coupled to one reference current generator 40. More specifically, three sense amplifiers 30_0_0, 30_1_0, and 30_2_0 are coupled to one reference current generator 40_0. Similarly, three sense amplifiers 30_0_1, 30_1_1, and 30_2_1 are coupled to one reference current generator 40_1, and three sense amplifiers 30_0_k, 30_1_k, and 30_2_k are coupled to one reference current generator 40_k. Thus, there are 3(k+1) sense amplifiers 30 corresponding to one mat MAT, and there are (k+1) reference current generators 40 connected thereto.

Of the three sense amplifiers 30 coupled to the one reference current generator 40, any one of the sense amplifiers 30 corresponding to a memory cell which is a read target is in an active state, and the other sense amplifiers 30 are in an inactive state.

The example shown in FIG. 6 shows a case where the sense amplifier 30 of j=0 is in an active state, and the sense amplifiers 30 of j=1, 2 are in an inactive state, at the time of reading data. More specifically, the sense amplifiers 30_0_0, 30_0_1, . . . , 30_0_k are in an active state, and a reference current Ir flows from those sense amplifiers 30 to the reference resistance elements RR. Furthermore, the sense amplifiers 30_1_0, 30_1_1, . . . , 30_1_k and the sense amplifier 30_2_0, 30_2_1, . . . , 30_2_k are in an inactive state, and a reference current Ir does not flow from those sense amplifiers 30 to the reference resistance elements RR.

Similarly, if the sense amplifier 30 of j=1 is in an active state, the sense amplifiers 30 of j=0, 2 are in an inactive state, and if the sense amplifier 30 of j=2 is in an active state, the sense amplifiers 30 of j=0, 1 are in an inactive state.

The reference current generator 40 includes an NMOS transistors (clamp transistors) M10 and a reference resistance element RR. The clamp transistors M10 respectively correspond to the sense amplifiers 30 coupled to the reference current generator 40, and the number of the included clamp transistors M10 is the same as those of the sense amplifiers 30. One end of each of the clamp transistors M10 is coupled to the second input terminal of the sense amplifier 30, and the other end is commonly coupled to one end of the reference resistance element RR. The gates of the clamp transistors M10 of the reference current generators 40 corresponding to one mat MAT are commonly coupled, and a voltage Vref is applied thereto. A voltage Vref is used for controlling a reference current Ir supplied to the second input terminal of the sense amplifier 30. The clamp transistor M10 clamps a voltage applied to the reference resistance element RR in accordance with a voltage Vref. The other end of the reference resistance element RR is grounded.

Note that the case where three sense amplifiers 30 are connected to one reference current generator 40 has been explained in the present embodiment; however, the above-explained case is applicable to a case where at least two sense amplifiers 30 are connected, and the sense amplifiers 30 are in a relationship in which any one of the sense amplifiers 30 is set in an active state, and the other sense simplifiers 30 are in an inactive step when data is read.

1. 1. 5 Plane Configuration of Sense Amplifier and Reference Current Generator

Next, the plane configuration of the sense amplifiers 30 and the reference current generators 40 will be explained, focusing on the arrangement of the clamp transistor M10 and the reference resistance element RR of the reference current generator 40 and the sense amplifiers 30.

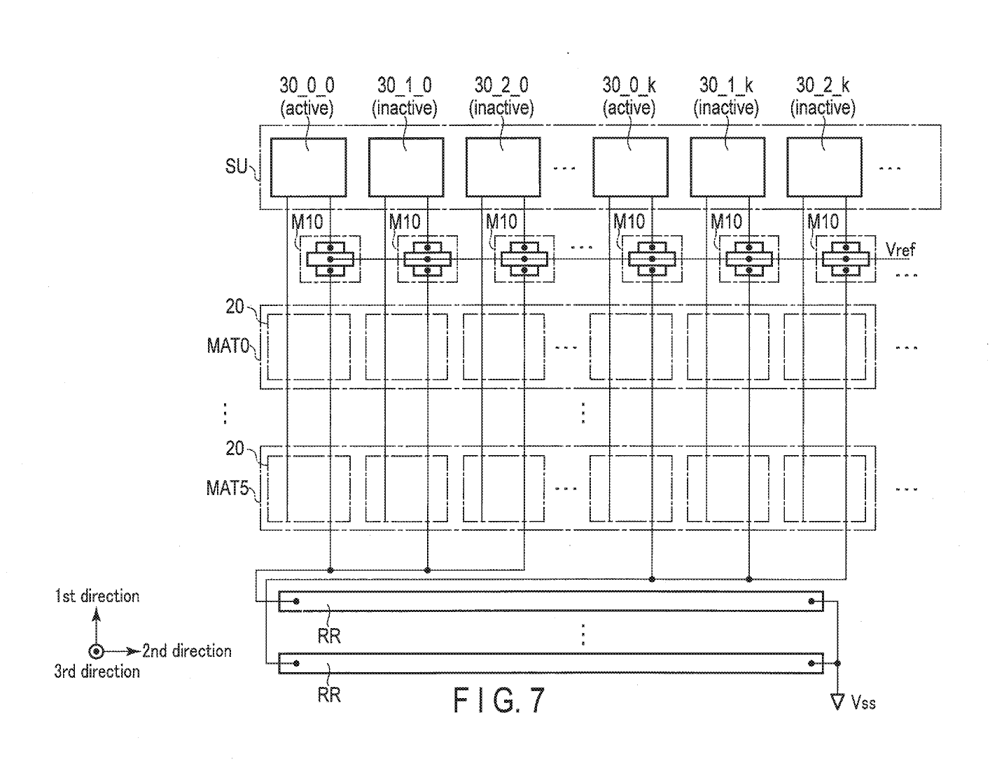

FIG. 7 is a plane view of the sense amplifiers 30 and the reference current generators 40 in the semiconductor memory device according to the first embodiment. Note that the example shown in FIG. 7 will be explained focusing on a plurality of sense amplifiers 30 coupled to the mats MAT0 to MAT5 arranged on the same column and the reference current generators 40 corresponding to the sense amplifiers 30.

As shown in FIG. 7, the sense unit SU, the clamp transistor M10, the mats MAT0 to MAT5, and a plurality of reference resistance elements RR are arranged along a first direction which is horizontal to the semiconductor substrate surface in said order. A plurality of sense amplifiers 30 are arranged along a second direction perpendicular to the first direction and horizontal to the semiconductor substrate surface. Similarly, a plurality of clamp transistors M10 are arranged along the second direction. In each of the mats MAT, the cell arrays 20 are arranged along the second direction. The first input terminal of the sense amplifier 30 is coupled to the cell arrays 20 of each of the mats MAT arranged along the first direction with the first input terminal, and the second input terminal of the sense amplifier 30 is coupled to one end of the clamp transistor M10 arranged along the first direction with the second input terminal. Furthermore, the three adjacent sense amplifiers 30 along the second direction, specifically the sense amplifiers 30_0_0, 30_1_0, and 30_2_0, for example, are commonly coupled to one end of the reference resistance element RR respectively via the clamp transistors M10. One end of the clamp transistor M10 is coupled to the sense amplifier 30 arranged along the first direction, and the other end is coupled to the reference resistance element RR. The gates of the clamp transistors M10 arranged along the second direction are commonly coupled, and a voltage Vref is applied thereto. The other end of the reference resistance element RR is grounded. In each of the mats MAT, the cell arrays 20 coupled to each of the sense amplifiers 30_0_0, 30_1_0, and 30_2_0, for example, are adjacent along the second direction, similarly to the sense amplifiers 30_0_0, 30_1_0, and 30_2_0, for example.

Note that, although the case has been explained where the sense unit SU, the clamp transistor M10, the mats MAT, and the reference resistance elements RR are arranged along the first direction in said order, the arrangement can be changed arbitrarily. For example, the mats MAT may be arranged after the sense unit SU. Furthermore, the case where a plurality of reference resistance elements RR are arranged along the first direction has been explained; the plurality of reference resistance elements RR may be arranged along the second direction, or may be arranged in a matrix, and may be arranged in the peripheral circuit unit 11; thus, the location of the plurality of reference resistance elements RR is not limited. The sense amplifiers 30 may be arranged in a staggered arrangement.

1. 2 Read Operation

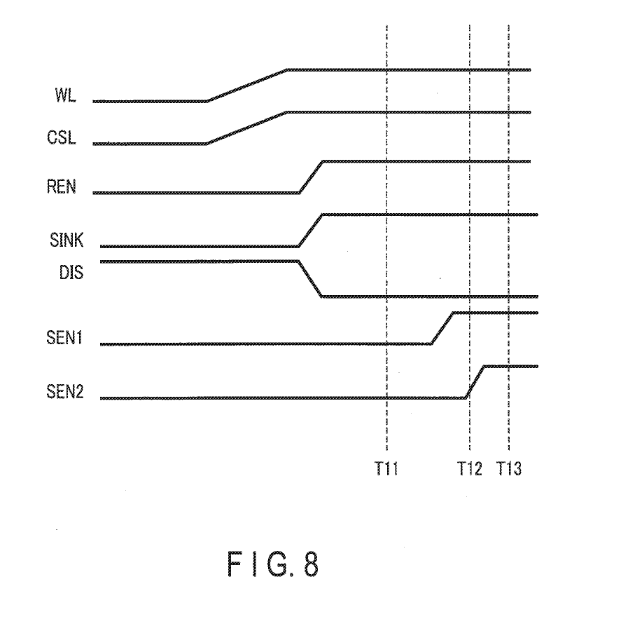

Next, the read operation will be explained. FIG. 8 is a timing chart indicating a read operation at the semiconductor memory device according to the first embodiment.

First, as shown in FIG. 8, in a standby state before the read operation starts (before time T11), the sense enable signal SEN1 is at an “L” level, and the sense enable transistors PM33 and PM34 are in an on state. The discharge signal DIS is at an “H” level, and the discharge transistors M6 and M8 are in an on state.

The word line WL, the column selection signal CSL<m>, the sink signal SINK, the sense enable signal SEN2, the signal SOE, and the read enable signal REN are at the “L” level, and the signal SOEb is at the “H” level. Thus, the MOS transistors input those signals are turned to an off state. The clamp transistor M4 clamps a voltage in accordance with the clamp signal Vclamp.

Next, at the initial state of the read operation (time T11), the sense enable signal SEN1 is at the “L” level, and the node OUT and the node OUTb are pre-charged at a source voltage VDD.

The column selection signal CSL<m> is turned to the “H” level, and the local bit line LBL<m> and the local source line LSL<m> are selected. Furthermore, the word line WL<n_0> is driven, and a memory cell MC as a read target is selected. The discharge signal DIS is turned to the “L” level, and the discharge transistors M6 and M8 are turned to an off state. The sink signal SINK is turned to the “H” level, and the sink transistor M3 is turned to an on state. The timing when the sink transistor M3 is turned to an on state is set before a read current flowed to the memory cell MC.

In the sense amplifier 30 in an active state, the read enable signal REN is at the “H” level, and the read enable transistor M5 is in an on state.

Next, at time T12, in the sense amplifier 30 in an active state, the sense enable signal SEN1 is at the “H” level, and the sense enable transistors PM33 and PM34 are in an off state. Thus, the pre-charge of the node OUT and the pre-charge of the node OUTb are stopped. As a result, the read current is supplied by the source voltage VDD applied to one end of each of the NMOS transistors PM31 and PM32. At this time, the read current changes in accordance with the data (“0” or “1”) stored in the selected memory cell MC. In other words, the read current changes in accordance with whether the selected memory cell MC is in a low-resistance state or in a high-resistance state.

After that, at time T13, in the sense amplifier 30 in an active state, the sense enable signal SEN2 is turned to the “H” level, and the sense enable transistors NM33 and NM34 are turned to an on state. Thus, the read current flowing in the first input terminal of the sense amplifier 30 and the reference current Ir flowing in the second input terminal are compared. The “H” level or “L” level is retained at a latch circuit consisting of the PMOS transistors PM31 and PM 32 and the transistors NM31 and NM32, in accordance with a comparison result.

Finally, the output enable signal SOE is turned to the “H” level, and the output enable signal SOEb is turned to the “L” level, and the NMOS transistors NM35 and NM36 and the PMOS transistors PM35 and PM36 are turned to an on state. Thus, the “H” level or “L” level retained at the latch circuit is output as an output signal from each of the node OUT and the node OUTb.

During data reading by the sense amplifier 30 that is in an active state, the read enable signal REN is set to “L” level, or a standby state is maintained in the sense amplifier 30 in an inactive state.

1. 3 Advantageous Effects of Present Embodiment

With the configuration according to the embodiment, it is possible to reduce a chip area without decreasing read data reliability. This effect will be explained herein below.

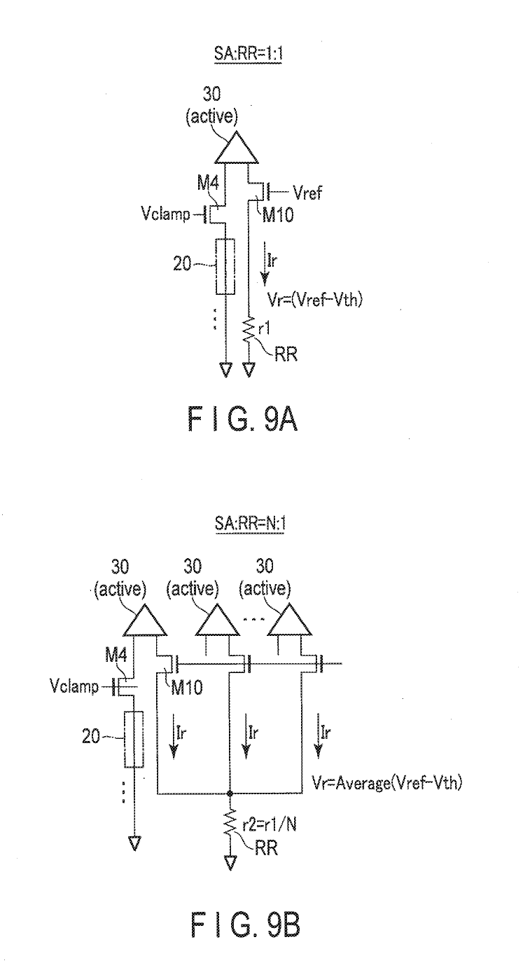

FIGS. 9A and 9B show an exemplary connection between the sense amplifiers 30 and the reference resistance elements RR according to a comparison example. As shown in FIG. 9A, when one reference resistance element RR (the reference current generator 40) is coupled to one sense amplifier 30 (SA:RR=1:1), the resistance value r1 of the reference resistance element RR is defined as r1=(Vref−Vth)/Ir (Vth is a threshold voltage of the transistor M10). Since it is necessary to have the same number of reference resistance elements RR as there are sense amplifiers 30, the proportion of the reference resistance elements RR to the chip area of the MRAM1 is large; thus, it is difficult to reduce the size of the MRAM 1 and to achieve high integration of the MRAM 1.

As shown in FIG. 9B, there is a case where N (N is an integer of 2 or more) sense amplifiers 30 share one reference resistance element RR (SA:RR=N:1). In this case, to supply a reference current Ir to N sense amplifiers 30, the resistance value r2 of the reference resistance element RR is set at r1/N. Thus, it is possible to reduce the number of reference resistance elements RR by sharing, and it is possible to reduce the resistance value of the reference resistance element RR, that is, the size of the reference resistance element RR. It should be noted that the variations in the reference current Ir will be significantly affected by the variations in the resistance value r2 of the reference resistance element RR, compared to the case where SA:RR=N:1. Because of the variations in the threshold voltage Vth in the clamp transistor M10 coupled to each of the sense amplifiers 30, the voltage Vr applied to the reference resistance element RR becomes an average of the voltage clamped by each of the clamp transistors M10 (i.e., Vref−Vth), that is, Vr=Average (Vref−Vth). For this reason, the variations in the reference current Ir provided to each of the sense amplifiers 30, compared to the case where SA:RR=N:1 become greater. Thus, if the variations in the reference current Ir become greater during the read operation, the possibility that an erroneous determination occurs in determining “0” data and “1” data in the sense amplifier 30 increases.

In contrast, in the configuration according to the present embodiment, a plurality of sense amplifiers 30 is coupled to one reference resistance element RR, that is, the reference current generator 40, and when data is read, one of the plurality of sense amplifiers 30 coupled to one reference resistance element RR is set to active, and the other sense amplifiers 30 are set to inactive. Consequently, one sense amplifier 30 is electrically coupled to one reference resistance element RR. For this reason, the resistance value of the reference resistance element RR becomes r1 similar to the case where SA:RR=1:1, and the voltage Vr applied to the reference resistance element RR is clamped by one clamp transistor M10 (i.e., Vref−Vth). As a result, it is possible to suppress the variations in the reference current Ir that occur in the case where a plurality of sense amplifiers 30 are connected to one reference resistance element RR. Thus, it is possible to reduce an erroneous determination between “0” data and “1” data in the sense amplifier 30, and to suppress degradation of the read data reliability. Since a plurality of sense amplifiers 30 share one reference resistance element RR, it is possible to reduce the area of the reference resistance element RR in the MRAM 1 and to decrease the chip area. Thus, it is possible to decrease the chip area without degrading the read data reliability.

### 2 Second Embodiment

Next, the semiconductor memory device according to the second embodiment will be explained. In the present embodiment, the layout of the sense amplifiers 30 and the reference current generator 40 different from those disclosed in the first embodiment will be explained. In the following, only the matters different from the first embodiment will be explained.

2. 1 First Example of Layout

First, the first example of layout will be explained. In this example, the arrangement of the sense amplifier 30 corresponding to one mat MAT, more specifically the arrangement of the sense amplifier 30 in an active state and the sense amplifier 30 in an inactive state, is different from that in the first embodiment.

2. 1. 1 Configuration of Reference Current Generator

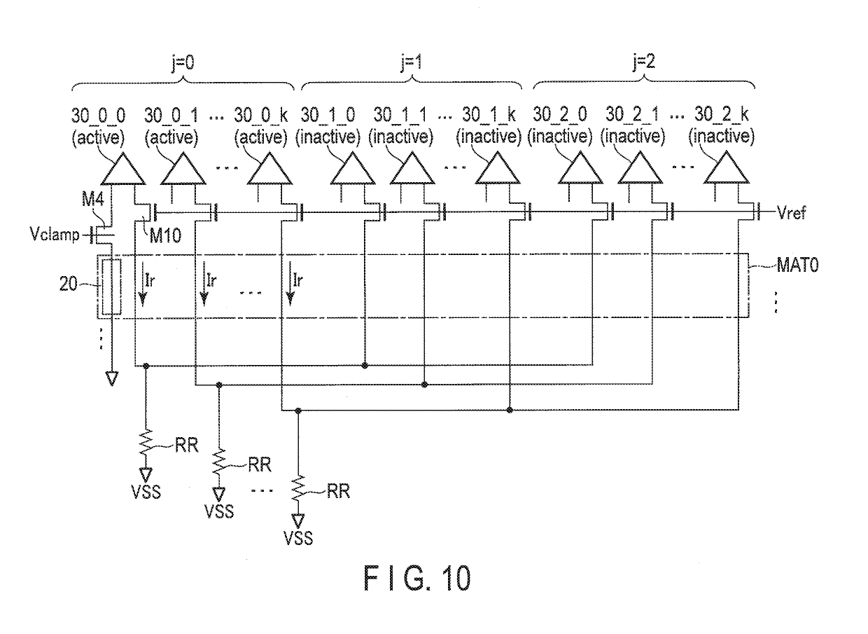

The configuration of the reference current generator will be explained. FIG. 10 is a circuit diagram of the reference current generators 40 at the semiconductor memory device according to the first example of the second embodiment.

As shown in FIG. 10, the connection between the sense amplifier 30, the clamp transistor M10, and the reference resistance element RR is the same as that shown in FIG. 6 according to the first embodiment. In other words, three each of sense amplifiers (30_0_k, 30_1_k, and 30_2_k) is commonly connected to one reference resistance element RR via the clamp transistor M10.

2. 1. 2 Plane Configuration of Sense Amplifier and Reference Current Generator

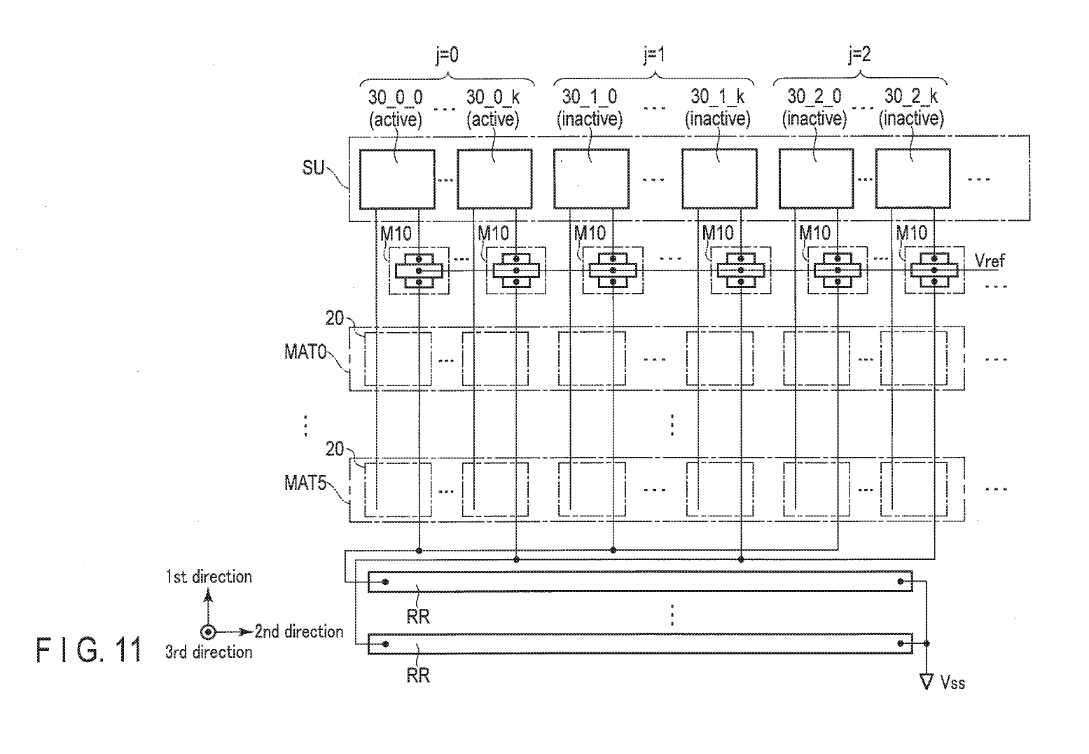

Next, the plane configuration of the sense amplifier 30 and the reference current generator 40 will be explained. FIG. 11 is a plane view of the sense amplifiers 30 and the reference current generators 40 in the semiconductor memory device according to the first example of the second embodiment.

As shown in FIG. 11, in the sense unit SU, along the second direction, k sense amplifiers 30 of j=0, that is, the sense amplifiers 30_0_0 to 30_0_k, are arranged, k sense amplifiers 30 of j=1, that is, the sense amplifiers 30_1_0 to 30_1_k, are arranged, and k sense amplifiers 30_2_0 to 30_2_k, are arranged. Furthermore, each of the 0th sense amplifiers 30 of j=0, 1, and 2 for example, that is, each of the sense amplifiers 30_0_0, 30_1_0, and 30_2_0, is commonly coupled to one reference resistance element RR via the clamp transistor M10. Thus, the sense amplifiers 30 (and the cell arrays 20 in each of the mat MAT coupled to the sense amplifiers 30) do not have to be adjacent along the second direction, and the order of the sense amplifiers 30 in an active state and the sense amplifiers 30 in an inactive state in the arrangement can be arbitrarily changed.

2. 2 Second Example of Layout

Next, the second example of layout will be explained. In this example, the layout of the sense amplifiers 30 and the reference resistance element RR in one quarter bank QBANK will be explained. More specifically, the sense amplifier 30 in an active state and the sense amplifiers 30 in an inactive state are commonly connected to one reference resistance element RR between mats MAT. In the following, although the quarter bank QBANK1 explained in the first embodiment with reference to FIG. 2 is taken as an example, the explanation is applicable to the other quarter banks QBANK.

In the present example, a sense amplifier 30 is expressed as sense amplifier 30_j_h. The variable j represents a number assigned to each of the sense amplifiers 30 included in one reference current generator 40 (in the present example, j=0, 1, 2, 3, 4, 5), and the variable h represents a number assigned to a the sense amplifier 30 corresponding to one mat MAT (h is an integer of 0 or more).

2. 2. 1 Configuration of Reference Current Generator

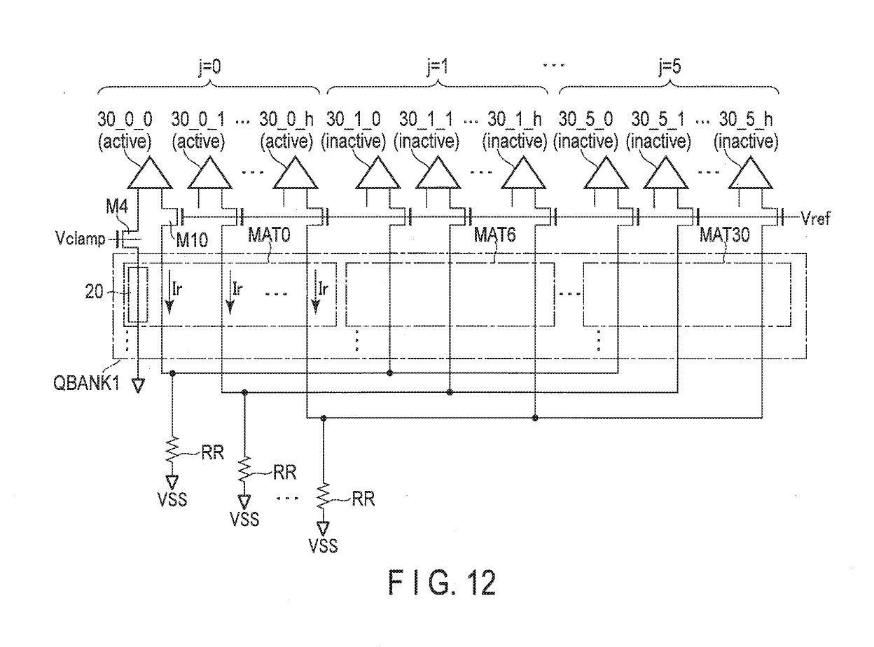

The configuration of the reference current generator will be explained. FIG. 12 is a circuit diagram of the reference current generators in the semiconductor memory device according to the second example of the second embodiment.

As shown in FIG. 12, the quarter bank QBANK1 contains six mats MAT on the same row (for example, the mats MAT0, MAT6, MAT12, MAT18, MAT24, and MAT30 explained in the first embodiment with reference to FIG. 2). One sense amplifier 30 corresponding to each mat MAT is commonly coupled to one reference resistance element RR (reference current generator 40). In other words, six sense amplifiers 30 are commonly coupled to one reference resistance element RR. More specifically, if j=0, 1, 2, 3, 4, 5 is respectively assigned to each of the sense amplifiers 30 corresponding to the mats MAT0, MAT6, MAT12, MAT18, MAT24, and MAT30, the h-th sense amplifiers 30 corresponding to each of the mats MAT for example, in other words, the sense amplifiers 30_0_h, 30_1_h, 30_2_h, 30_3_h, 30_4_h, and 30_5_h, are coupled to one reference resistance element RR. Thus, the number of the reference current generators 40 corresponding to one quarter bank QBANK becomes (h+1). The number of the sense amplifiers 30 corresponding to one quarter bank QBANK becomes 6(h+1).

In the example shown in FIG. 12, since the mat MAT0 (j=0) is in an active state, a reference current Ir flows from each of the sense amplifiers 30_0_0, 30_0_1, . . . , 30_0_h to the reference resistance element RR via the transistor M10.

Note that the case where the six sense amplifiers 30 corresponding to the six mats MAT arranged on the same row are commonly coupled to one reference resistance element RR has been explained in the present example; however, at least the sense amplifiers 30 corresponding to two or more mats MAT arranged in the same row should be commonly coupled to one reference resistance element RR. For example, the sense amplifiers 30_0_0, 30_1_0, and 30_2_0 respectively corresponding to the mats MAT0, MAT6, and MAT12 may be commonly coupled to one reference resistance element RR, and the sense amplifiers 30_3_0, 30_4_0, and 30_5_0 respectively corresponding to the mats MAT18, MAT24, and MAT30 may be commonly coupled to one reference resistance element RR.

2. 2. 2 Plane Configuration of Sense Amplifier and Reference Current Generator

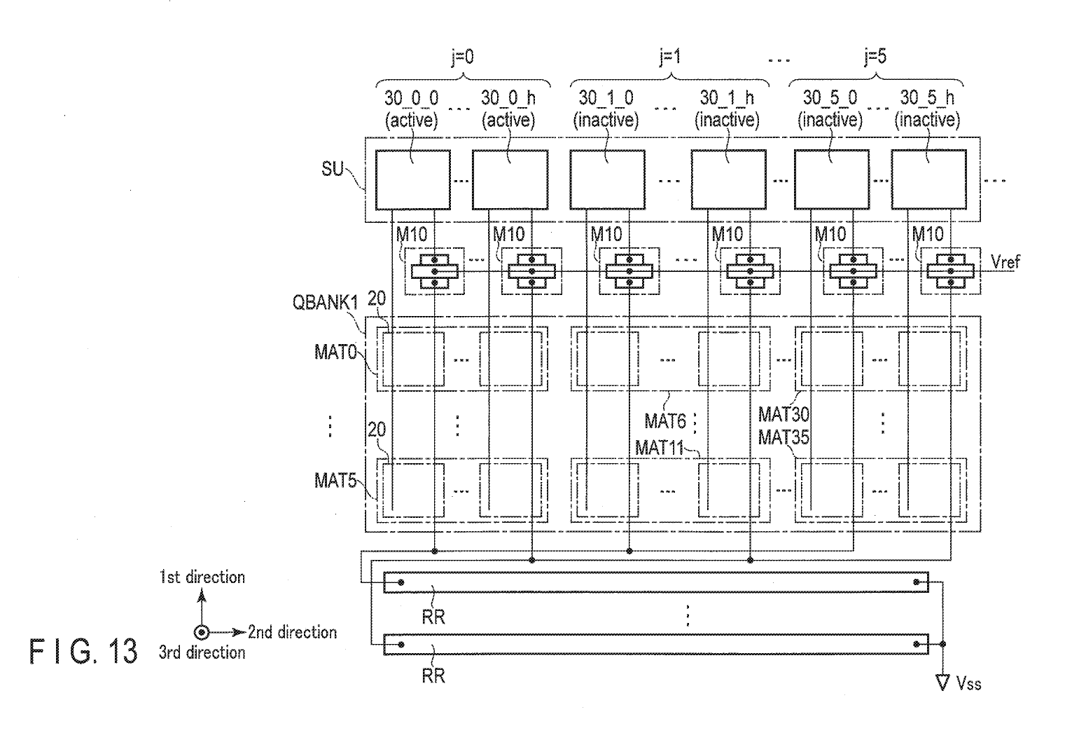

Next, the plane configuration of the sense amplifier 30 and the reference current generator 40 will be explained. FIG. 13 is a plane view of the sense amplifiers 30 and the reference current generators 40 in the semiconductor memory device according to the second example of the second embodiment.

As shown in FIG. 13, in the quarter bank QBANK1, 6×6=36 mats MAT are arranged in a matrix along the first and second directions respectively.

(h+1) sense amplifiers corresponding to each of the mats MAT are arranged along the second direction. Specifically, (h+1) sense amplifiers 30 of j=0 corresponding to the mats MAT0 to MAT5, that is, the sense amplifiers 30_0_0 to 30_0_h are arranged. Similarly, (h+1) sense amplifiers 30 of j=1 to 5 are respectively arranged along the second direction.

Furthermore, the h-th sense amplifiers 30 corresponding to the mats (j=0 to 5) for example, that is, each of the sense amplifiers 30_0_h, 30_1_h, 30_2_h, 30_3_h, 30_4_h, and 30_5_h is commonly coupled to one reference resistance element RR via the clamp transistor M10. Thus, the sense amplifiers 30 coupled to one reference resistance element RR may be commonly coupled among the mats MAT.

2. 3 Third Example of Layout

Next, the third example of layout will be explained. In this example, the layout of the sense amplifiers 30 and the reference resistance elements RR in a plurality of quarter banks QBANK will be explained. More specifically, the sense amplifiers 30 in an active state and the sense amplifiers 30 in an inactive state are commonly coupled to one reference resistance element RR between quarter banks QBANK. In the following, a case where the sense amplifiers 30 of the quarter bank QBANK0 and the quarter bank QBANK1 are commonly connected to one reference resistance element RR will be explained. Note that the quarter bank QBANK2 and the quarter bank QBANK3 have the same configuration.

2. 3. 1 Configuration of Reference Current Generator

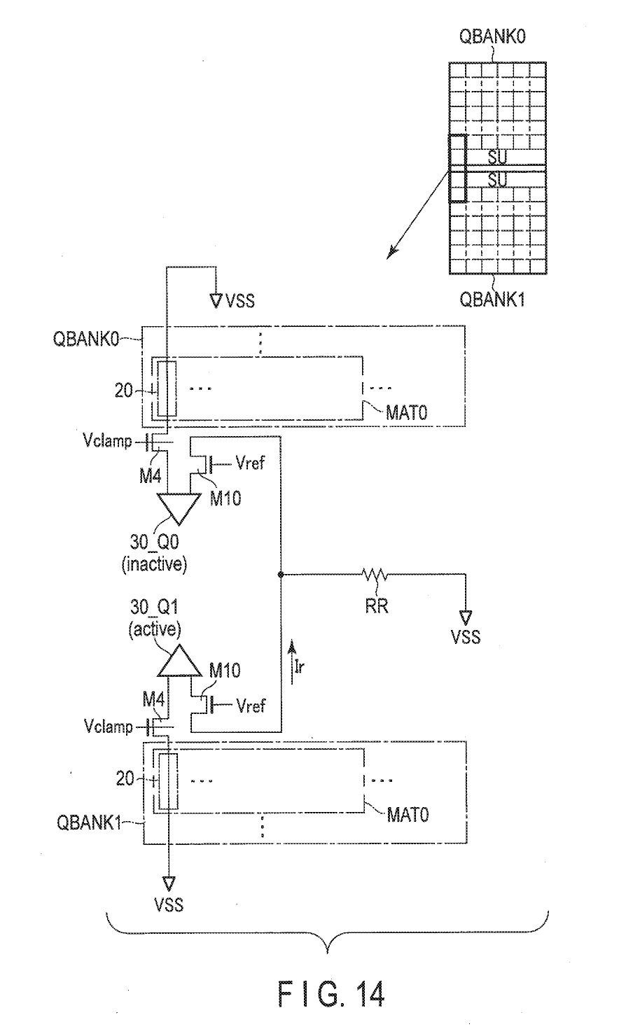

The configuration of the reference current generator will be explained. FIG. 14 is a circuit diagram of the reference current generator 40 at the semiconductor memory device according to the third example of the second embodiment.

As shown in FIG. 14, the sense amplifier 30 corresponding to the mat MAT0 of the quarter bank QBANK0 (hereinafter referred to as “30_Q0) and the sense amplifier 30 corresponding to the mat MAT0 of the quarter bank QBANK1 (hereinafter referred to as “30_Q1) are commonly coupled to one reference resistance element RR. In the example shown in FIG. 14, the sense amplifier 30_Q1 corresponding to the mat MAT0 of the quarter bank QBANK1 is set in an active state, and a reference current Ir flows from the sense amplifier 30_Q1 to the reference resistance element RR via the transistor M10. On the other hand, the sense amplifier 30_Q0 corresponding to the mat MAT0 of the quarter bank QBANK0 is set in an inactive state.

2. 3. 2 Plane Configuration of Sense Amplifier and Reference Current Generator

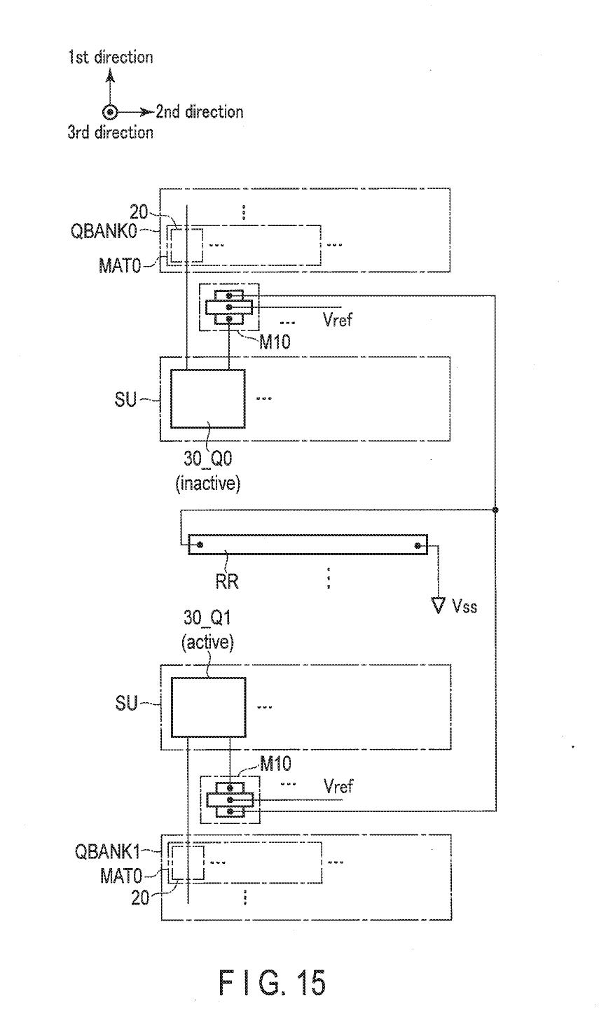

Next, the plane configuration of the sense amplifier 30 and the reference current generator 40 will be explained. FIG. 15 is a plane view of the sense amplifiers 30 and the reference current generator 40 in the semiconductor memory device according to the third example of the second embodiment.

As shown in FIG. 15, the quarter bank QBANK0, the clamp transistor M10, the sense unit SU corresponding to the quarter bank QBANK0, the reference resistance element RR, the sense unit SU corresponding to the quarter bank QBANK1, the clamp transistor M10, and the quarter bank QBANK1 are arranged along the first direction in this order. More specifically, a plurality of sense amplifiers 30 are arranged along the second direction in each sense unit SU. In each of the mats MAT, the cell arrays 30 are arranged along the second direction. In the quarter banks QBANK0 and QBANK1, the cell arrays 20 of the mats MAT respectively coupled to the first input terminals of the sense amplifiers 30_Q0 and 30_Q1 are arranged along the first direction. Furthermore, the sense amplifiers 30_Q0 and 30_Q1 arranged along the first direction are commonly coupled to one reference resistance elements RR respectively via the clamp transistors M10.

2. 4 Advantageous Effects of Present Embodiment

As described above, the layouts explained in the first embodiment can be applied to the configuration according to the present embodiment.

### 3. Examples of Variations

The semiconductor memory device according to the above embodiment includes a first and a second memory cell (MC in FIG. 4) each including a variable resistance element (VR in FIG. 4); a first sense amplifier (30_0_0 in FIG. 6) having a first input terminal coupled to the first memory cell; a second sense amplifier (30_1_0 in FIG. 6) having a first input terminal coupled to the second memory cell; and a first current generator (40 in FIGS. 4 and 6) including a first resistance element (RR in FIG. 6) coupled to a second input terminal of the first sense amplifier and a second input terminal of the second sense amplifier, and generating a first current which is based on the first resistance element is supplied to the first sense amplifier or the second sense amplifier. The first sense amplifier is set to an active state and the second sense amplifier is set to an inactive state in a read operation at the first memory cell.

By applying the above embodiment, it is possible to provide a semiconductor memory device that can decrease a chip area without degrading the read data reliability. Note that the embodiments are not limited to the above-explained aspects, and different variations are possible.

Furthermore, in the above embodiment, the sense amplifier 30 may be of a voltage sensing type.

Furthermore, in the above embodiment, the reference resistance element RR may be a diffusion layer resistance element or a gate resistance element; its configuration is not limited to the disclosure herein.

Note that the MRAM illustrated in each of the above embodiments may be a spin-transfer torque magnetoresistive random access memory (STT-MRAM) utilizing spin injection phenomena for magnetization inversion of a magnetic layer.

In each of the above embodiments, as a semiconductor memory device, an MRAM using a magnetoresistive effect element is explained as an example, but is not limited thereto. The embodiments can be applied to the semiconductor memory device which read the storing data according to the comparison of the current or the voltage in the memory cell. The embodiments can be applied to the semiconductor memory device which store the data using the variety of the resistance in the memory cell, such as a resistance change type memory similar to an MRAM, a resistive random access memory (ReRAM), and a phase-change random access memory (PCRAM).

While certain embodiments have been described, these embodiments have been presented by way of example only, and are not intended to limit the scope of the inventions. Indeed, the novel methods and systems described herein may be embodied in a variety of other forms; furthermore, various omissions, substitutions, and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor memory device comprising:
first and second memory cells each including a variable resistance element;
a first sense amplifier having a first input terminal coupled to the first memory cell;
a second sense amplifier having a first input terminal coupled to the second memory cell; and
a first current generator including a first resistance element coupled to a second input terminal of the first sense amplifier and a second input terminal of the second sense amplifier, and generating a first current which is based on the first resistance element and is supplied to the first sense amplifier or the second sense amplifier,
wherein the first sense amplifier is set to an active state and the second sense amplifier is set to an inactive state in a read operation of the first memory cell.

2. The device according to claim 1, wherein a resistance of the first resistance element is greater than a resistance of the variable resistance element in a low resistance state, and less than a resistance of the variable resistance element in a high resistance state.

3. The device according to claim 1, wherein in the read operation of the first cell memory, the first current is greater than a current flowing in the first input terminal of the first sense amplifier when the variable resistance element is at a high resistance state, and less than a current flowing in the first input terminal of the first sense amplifier when the variable resistance element is in a low resistance state.

4. The device according to claim 1, further comprising:
a first transistor coupled between the second input terminal of the first sense amplifier and the first current generator; and
a second transistor coupled between the second input terminal of the second sense amplifier and the first current generator,
wherein the first transistor is set to an on-state and the second transistor is set to an off-state in the read operation of the first memory cell.

5. The device according to claim 1, wherein a standby state of the second sense amplifier is maintained in the read operation of the first memory cell.

6. The device according to claim 1, wherein the first sense amplifier and the second sense amplifier are adjacently arranged.

7. The device according to claim 1, further comprising:
third and fourth memory cells each including a variable resistance element;
a third sense amplifier having a first input terminal coupled to the third memory cell;
a fourth sense amplifier having a first input terminal coupled to the fourth memory cell; and
a second current generator including a second resistance element coupled to a second input terminal of the third sense amplifier and a second input terminal of the fourth sense amplifier, and generating a second current which is based on the second resistance element and is supplied to the third amplifier or the fourth sense amplifier,
wherein the first sense amplifier, the third sense amplifier, and the second sense amplifier are arranged along a first direction in said order.

8. The device according to claim 1, further comprising:
a first cell array including the first memory cell; and
a second cell array including the second memory cell,
wherein the first cell array, the first sense amplifier, the first resistance element, the second sense amplifier, and the second cell array are arranged along a first direction in said order.

9. The device according to claim 1, wherein the first current generator further includes:
a first transistor of which one end is coupled to the second input terminal of the first sense amplifier and the other end is coupled to the first resistance element, and in which a second voltage is applied to a gate; and
a second transistor of which one end is coupled to the second input terminal of the second sense amplifier and the other end is coupled to the first resistance element, and in which the second voltage is applied to a gate.

10. The device according to claim 1, wherein the device is an MRAM.

11. The device according to claim 1, wherein the variable resistance element is a magnetoresistive effect element.

12. The device according to claim 4, wherein the first and second transistors are NMOS transistors.

13. The device according to claim 7, further comprising a first mat,
wherein the first mat includes:
a first cell array including the first memory cell;
a second cell array including the second memory cell;
a third cell array including the third memory cell; and
a fourth cell array including the fourth memory cell, and
the first cell array, the third cell array, and the second cell array are arranged along the first direction in said order.

14. The device according to claim 7, further comprising a first mat and a second mat,
wherein the first mat includes:
a first cell array including the first memory cell; and
a third cell array including the third memory cell,
the second mat includes:
a second cell array including the second memory cell; and
a fourth cell array including the fourth memory cell,
the first mat and the second mat are arranged along the first direction in said order, and
the first cell array, the third array, and the second cell array are arranged along the first direction in said order.

15. The device according to claim 8, further comprising:
a first bank including a first mat having the first cell array;
a second bank including a second mat having the second cell array;
a first sense unit including the first sense amplifier; and
a second sense unit including the second sense amplifier,
wherein the first bank, the first sense unit, the first resistance element, the second sense unit, and the second bank are arranged along the first direction in said order.

16. The device according to claim 9, wherein the first and second transistors are NMOS transistors.

17. The device according to claim 9, wherein the first current generator controls the first current in accordance with the second voltage.

18. A semiconductor memory device comprising:
memory cells each including a variable resistance element;
sense amplifiers having first input terminals coupled to the memory cells, respectively; and
a current generator including a resistance element coupled to second input terminals of the sense amplifiers, and generating a current which is based on the resistance element and is supplied to at least one of the sense amplifiers,
wherein at least one of the sense amplifiers is set to an active state, and the other sense amplifiers are set to an inactive state in a read operation.

19. A semiconductor memory device comprising:
first and second memory cells each including an element storing a data;
a first sense amplifier having a first input terminal coupled to the first memory cell;
a second sense amplifier having a first input terminal coupled to the second memory cell; and
a current generator including a resistance element coupled to a second input terminal of the first sense amplifier and a second input terminal of the second sense amplifier, and generating a current which is based on the resistance element and is supplied to the first sense amplifier or the second sense amplifier,
wherein the first sense amplifier is set to an active state and the second sense amplifier is set to an inactive state in a read operation of the first memory cell.
